(19) United States
(12) Patent Application Publication
(10) Pub. No.: US 2020/0012186 A1
(43) Pub. Date: Jan. 9, 2020

(54) PATTERN WIDTH CORRECTION SYSTEM AND METHOD FOR MANUFACTURING A SEMICONDUCTOR DEVICE USING THE SAME

(71) Applicant: SAMSUNG ELECTRONICS CO., LTD., Suwon-si (KR)

(72) Inventors: Sung Min Ahn, Suwon-si (KR); Sang-Hyun Park, Yongin-si (KR); Byoung Min Yun, Hwaseong-si (KR); Jae Young Jang, Suwon-si (KR)

(21) Appl. No.: 16/261,105

(22) Filed: Jan. 29, 2019

(30) Foreign Application Priority Data
Jul. 6, 2018 (KR) 10-2018-0078657

(51) Int. Cl. G03F 1/36; G03F 1/44; G03F 1/68; G03F 7/20

(52) U.S. Cl. CPC G03F 1/36; G03F 7/70291; G03F 1/68; G03F 1/44

(57) ABSTRACT

A pattern width correction system includes a pattern width measurement unit configured to measure a width of a first pattern formed at a first distance, where the first pattern is formed by irradiating first light modulated using first pattern data, a first error data calculator configured to generate first error data on the basis of the measured width of the first pattern, a regression analyzer configured to perform regression analysis on the first error data to generate a first relational expression between X-Y coordinates of the first pattern and a width error of the first pattern, a second error data calculator configured to generate second error data in a manipulation area having a second distance by using the first relational expression, and a pattern data correction unit configured to generate second pattern data by correcting the first pattern data on the basis of the second error data.

### CROSS-REFERENCE TO RELATED APPLICATION

This application claims priority under 35 U.S.C. 119 to Korean Patent Application No. 10-2018-0078657, filed on Jul. 6, 2018 in the Korean Intellectual Property Office, the disclosure of which is incorporated by reference herein in its entirety.

### TECHNICAL FIELD

Exemplary embodiments of the inventive concept relate to a pattern width correction system and a method of manufacturing a semiconductor device using the same.

### DISCUSSION OF RELATED ART

Generally, a method of forming a pattern on a substrate contained in a liquid crystal display (LCD), a plasma display panel (PDP), a flat panel display (FPD), an organic light-emitting diode (OLED) panel, or the like includes applying a pattern material onto the substrate, and selectively exposing the pattern material using a photomask to selectively remove a specific pattern material part having a changed chemical property or the remaining parts other than the specific pattern material pattern, thus forming the pattern.

However, as the size of substrates is gradually increased and the precision of patterns is also gradually increased, a maskless exposure apparatus capable of forming a desired pattern on a substrate without using a photomask has been developed recently. The maskless exposure apparatus forms a pattern by transferring light beams onto the substrate with pattern information formed as electric signals by means of an electronic device. A representative example of the electronic device is a digital micromirror device (DMD). In a DMD, a pattern is exposed on an exposure surface with only needed light by a plurality of micromirrors transmitting, at a desired angle, light incident at the desired angle and transmitting, at other angles, light incident at the other angles.

### SUMMARY

According to an exemplary embodiment of the inventive concept, a pattern width correction system includes a pattern width measurement unit configured to measure a width of a first pattern formed at a first distance, where the first pattern is formed by irradiating first light modulated using first pattern data, a first error data calculator configured to generate first error data on the basis of the measured width of the first pattern, a regression analyzer configured to perform regression analysis on the first error data to generate a first relational expression between X-Y coordinates of the first pattern and a width error of the first pattern, a second error data calculator configured to generate second error data in a manipulation area having a second distance by using the first relational expression, and a pattern data correction unit configured to generate second pattern data by correcting the first pattern data on the basis of the second error data.

According to an exemplary embodiment of the inventive concept, a pattern width correction system includes a pattern forming unit configured to form a first pattern on a substrate using first pattern data, a pattern width measurement unit configured to measure a width of the first pattern, and a pattern width correction unit configured to generate first error data of the measured width of the first pattern, generate a first relational expression of a location of the substrate and a width error of the first pattern using the first error data, calculate the width error of the first pattern at a first location of the substrate by substituting the first location into the first relational expression, and generate second pattern data obtained by correcting the first pattern data at the first location using the width error of the first pattern at the first location.

According to an exemplary embodiment of the inventive concept, a method of manufacturing a semiconductor apparatus includes forming a first pattern on a first substrate using first pattern data, generating second pattern data obtained by correcting the first pattern data using the first pattern, and forming a second pattern on a second substrate using the second pattern data. The generating of the second pattern data includes measuring a width of the first pattern, generating first error data of the measured width of the first pattern, generating a first relational expression between a location of the first substrate and a width error of the first pattern using the first error data, calculating the width error of the first pattern at a first location of the first substrate by substituting the first location into the first relational expression, and generating the second pattern data using the width error of the first pattern at the first location.

### BRIEF DESCRIPTION OF THE DRAWINGS

The above and other aspects and features of the inventive concept will become more apparent by describing in detail exemplary embodiments thereof with reference to the attached drawings.

FIG. 1 is a block diagram illustrating a pattern width correction system according to an exemplary embodiment of the inventive concept.

FIG. 2 is a diagram illustrating a configuration of a pattern forming unit of FIG. 1 according to an exemplary embodiment of the inventive concept.

FIG. 3 is diagram illustrating a width of a pattern according to an exemplary embodiment of the inventive concept.

FIG. 4 is a block diagram illustrating a pattern width correction unit of FIG. 1 according to an exemplary embodiment of the inventive concept.

FIG. 5 is a flowchart illustrating a pattern width correction method according to an exemplary embodiment of the inventive concept.

FIG. 6 is a diagram illustrating a first pattern formed on a substrate according to an exemplary embodiment of the inventive concept.

FIG. 7 is a diagram illustrating a width of the first pattern of FIG. 6 according to an exemplary embodiment of the inventive concept.

FIG. 8 is a diagram illustrating a first relational expression between X-Y coordinates and an error of the width of the first pattern of FIG. 7 according to an exemplary embodiment of the inventive concept.

FIGS. 9 and 10 are diagrams illustrating second error data and a manipulation area of a second distance according to an exemplary embodiment of the inventive concept.

FIG. 11 is a diagram illustrating vector data and bitmap data according to an exemplary embodiment of the inventive concept.

FIG. 12 is a diagram illustrating isotropic error correction according to an exemplary embodiment of the inventive concept.

FIG. 13 is a diagram illustrating anisotropic error correction according to an exemplary embodiment of the inventive concept.

FIG. 14 is a flowchart illustrating a pattern width correction method according to an exemplary embodiment of the inventive concept.

FIG. 15 is a diagram illustrating second bitmap data generated by performing a morphology operation on first bitmap data according to an exemplary embodiment of the inventive concept.

FIG. 16 is a flowchart illustrating a method of manufacturing a semiconductor apparatus using a pattern width correction method according to an exemplary embodiment of the inventive concept.

### DETAILED DESCRIPTION OF THE EMBODIMENTS

Exemplary embodiments of the inventive concept provide a pattern width correction system for making a critical dimension (CD) uniform over an entire substrate.

Exemplary embodiments of the inventive concept also provide a method of manufacturing a semiconductor apparatus having a uniform CD on the whole.

Exemplary embodiments of the inventive concept will be described more fully hereinafter with reference to the accompanying drawings. Like reference numerals may refer to like elements throughout this application.

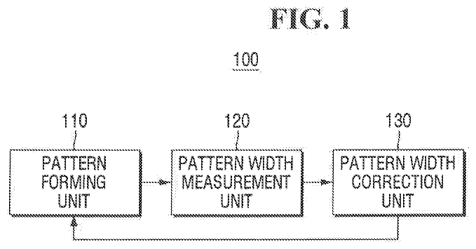

FIG. 1 is a block diagram illustrating a pattern width correction system according to an exemplary embodiment of the inventive concept.

Referring to FIG. 1, a pattern width correction system 100 according to an exemplary embodiment of the inventive concept may include a pattern forming unit 110, a pattern width measurement unit 120, and a pattern width correction unit 130.

The pattern forming unit 110 may form a pattern designed using pattern data. For example, the pattern forming unit 110 may form a first pattern using first pattern data and may form a second pattern using second pattern data. The second pattern data may be obtained by correcting the first pattern data. A detailed description thereof will be provided below.

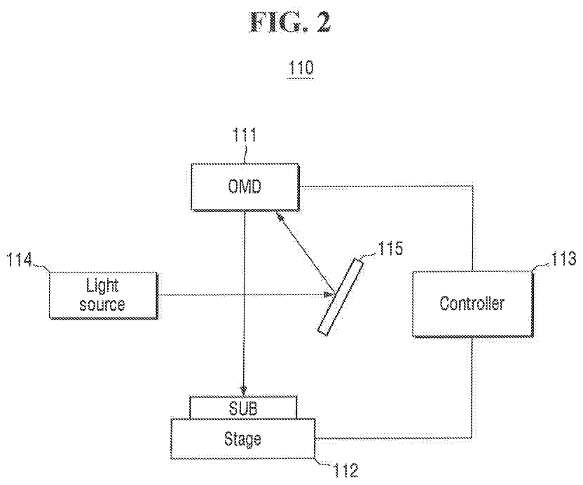

The pattern forming unit 110 according to an exemplary embodiment of the inventive concept may include a maskless exposure device, which will be described below with reference to FIG. 2.

FIG. 2 is diagram illustrating a configuration of a pattern forming unit of FIG. 1 according to an exemplary embodiment of the inventive concept. For convenience of description, FIG. 2 shows only some elements of the pattern forming unit 110. Referring to FIG. 2, the pattern forming unit 110 may include an optical modulation device (OMD) 111, a stage 112, a controller 113, a light source 114, and a reflection mirror 115. The OMD 111 may include a spatial light modulator (SLM). For example, the OMD 111 may be a microelectromechanical system (MEMS)-type digital micromirror device (DMD), a two-dimensional grating light valve (GLV), an electric optical element using lead zirconate titanate (PZT), which is a light-transmitting ceramic, or a Ferroelectric Liquid Crystal (FLC). Here, for convenience of description, it is assumed that the OMD 111 uses a MEMS-type DMD. A substrate SUB for forming a pattern may be mounted on the stage 112. The stage 112 may be moved in an X direction and a Y direction under the control of the controller 113 to be described below.

The controller 113 may provide pattern data to the OMD 111. The pattern data may be data associated with turning the OMD 111 on/off. The DMD included in the OMD 111 may be tilted according to the pattern data. For example, the DMD included in the OMD 111 may be set to a first angle according to the pattern data to irradiate desired light to the substrate SUB. As another example, the DMD included in the OMD 111 may be set to a second angle according to the pattern data to prevent undesired light from being irradiated to the substrate SUB.

The controller 113 may provide a stage control signal to the stage 112. The stage 112 may be moved in an X direction or a Y direction according to the stage control signal. The stage control signal may be synchronized with, for example, the pattern data. In other words, the controller 113 may provide the pattern data to the OMD 111 and may also adjust the movement of the stage 112 to form a desired pattern at a desired position on the substrate SUB.

The light source 114 may provide first light to the OMD 111 through the reflection mirror 115. In other words, the light source 114 may input incident light to the reflection mirror 115 and may reflect the first light to the OMD 111 in response to the incident light. In response to the first light provided to the OMD 111, the second light may be provided to the substrate SUB according to the pattern data provided by the controller 113.

The elements of the pattern forming unit 110 are not limited to those described above. The above-described elements may be omitted, and other elements may be added.

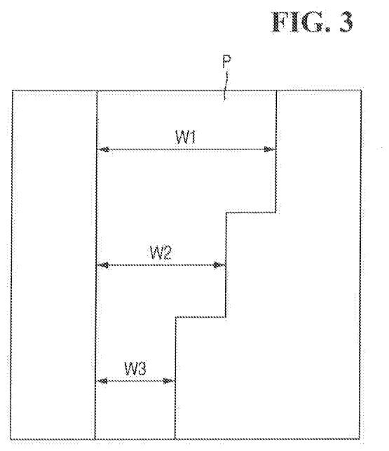

Referring to FIG. 1 again, the pattern formed by the pattern forming unit 110 may be provided to the pattern width measurement unit 120. For example, the pattern width measurement unit 120 may be a critical dimension (CD) meter. The pattern width measurement unit 120 may measure the width of the provided pattern. For example, the pattern width measurement unit 120 may measure the width of the provided pattern every first distance. The width of the pattern according to an exemplary embodiment of the inventive concept will be described with reference to FIG. 3 as an example.

FIG. 3 is a diagram illustrating a width of a pattern according to an exemplary embodiment of the inventive concept.

Referring to FIG. 3, a pattern P may include a first width W1, a second width W2, and a third width W3. The first width W1 may be greater than the second width W2, and the second width W2 may be greater than the third width W3. For convenience of description, the width of the pattern P according to an exemplary embodiment of the inventive concept is defined as the smallest width among the plurality of widths included in the pattern P. In other words, the width of the pattern P refers to a critical dimension (CD) of the pattern P. For example, referring to FIG. 3, the width of the pattern P may be the third width W3.

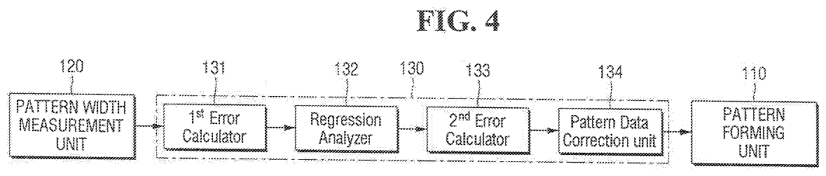

Referring to FIG. 1 again, the width of the pattern measured by the pattern width measurement unit 120 may be provided to the pattern width correction unit 130. The pattern width correction unit 130 may analyze and correct the width of the provided pattern and provide the width back to the pattern forming unit 110. This will be described further with reference to FIG. 4.

FIG. 4 is a block diagram illustrating a pattern width correction unit of FIG. 1 according to an exemplary embodiment of the inventive concept.

Referring to FIG. 4, the pattern width correction unit 130 may include a first error calculator 131, a regression analyzer 132, a second error calculator 133, and a pattern data correction unit 134.

According to an exemplary embodiment of the inventive concept, the first error calculator 131, the regression analyzer 132, the second error calculator 133, and the pattern data correction unit 134 are shown as separate elements, but the inventive concept is not limited thereto. In exemplary embodiments of the inventive concept, the first error calculator 131, the regression analyzer 132, the second error calculator 133, and the pattern data correction unit 134 are classified by functional differences for convenience of description and may physically be the same element. For example, the first error calculator 131, the regression analyzer 132, the second error calculator 133, and the pattern data correction unit 134 may be physically implemented as an analog circuit, a digital circuit such as a logical gate, an integrated circuit, a microprocessor, a microcontroller, a memory circuit, a passive electronic component, an active electronic component, an optical component, and/or a hardwired circuit.

According to an exemplary embodiment of the inventive concept, the first error calculator 131, the regression analyzer 132, the second error calculator 133, and the pattern data correction unit 134 may be driven by firmware or software.

According to an exemplary embodiment of the inventive concept, a circuit for implementing the first error calculator 131, the regression analyzer 132, the second error calculator 133, and the pattern data correction unit 134 may be implemented on, for example, a substrate support such as a printed circuit board (PCB) or one or more semiconductor chips. As another example, the circuit for implementing the first error calculator 131, the regression analyzer 132, the second error calculator 133, and the pattern data correction unit 134 may be implemented by a dedicated hardware device or a processor (e.g., one or more programmed microprocessors and associated circuits), or may be implemented by a combination of a dedicated hardware device that performs some functions of the first error calculator 131, the regression analyzer 132, the second error calculator 133, and the pattern data correction unit 134 and a processor that performs the remaining functions of the blocks.

The first error calculator 131 may generate first error data from the measured pattern width. According to an exemplary embodiment of the inventive concept, the first error data may include measured X-Y coordinates of the pattern (or X-Y coordinates of the substrate) and a measured error of the pattern width.

The regression analyzer 132 may perform regression analysis on the first error data generated by the first error calculator 131 to derive a first relational expression between the X-Y coordinates of the pattern (or the X-Y coordinates of the substrate) and the error of the pattern width.

The second error calculator 133 may generate second error data using the first relational expression generated by the regression analyzer 132. The second error data may include X-Y coordinates corresponding to a first location on the substrate (or the pattern) and a result value obtained by substituting the X-Y coordinates corresponding to the first location into the first relational expression.

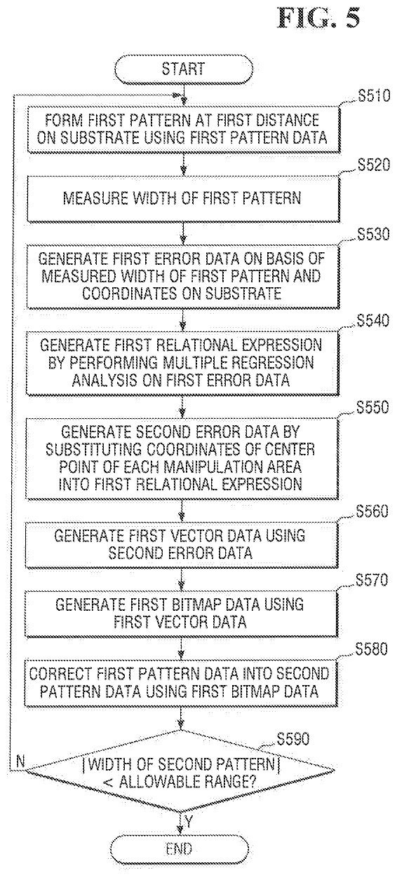

The pattern data correction unit 134 may correct the first pattern data on the basis of the second error data generated by the second error calculator 133. For convenience of description, the corrected first pattern data is referred to as the second pattern data. The second pattern data may be provided to the pattern forming unit 110. The following detailed description will be made with reference to FIGS. 5 to 13.

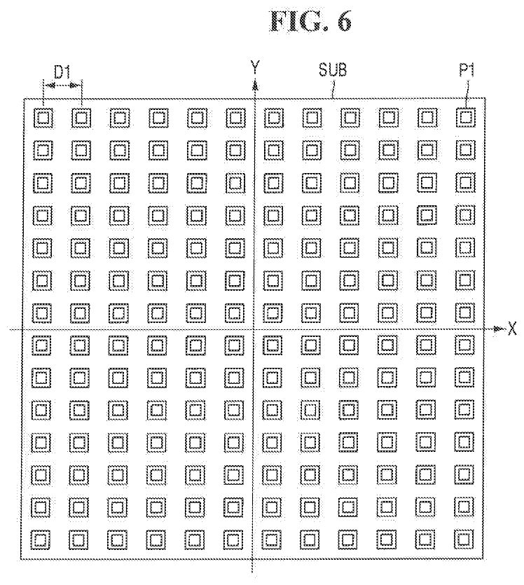

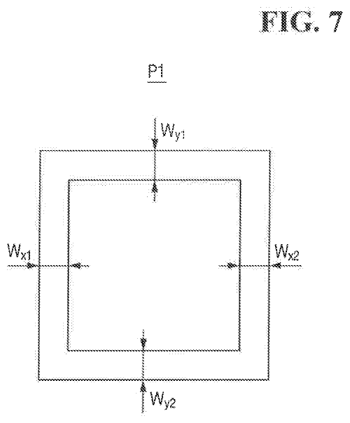

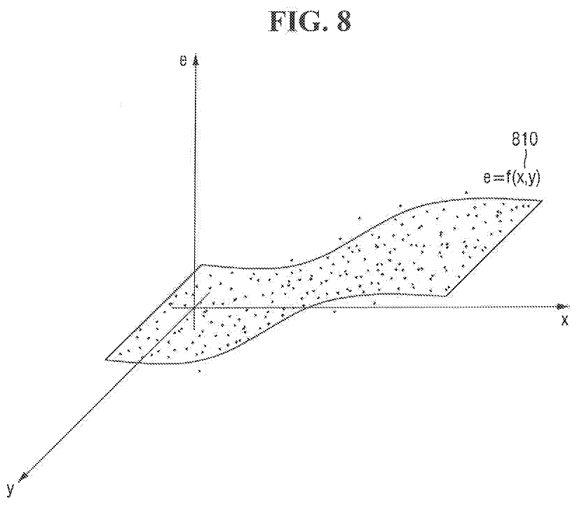

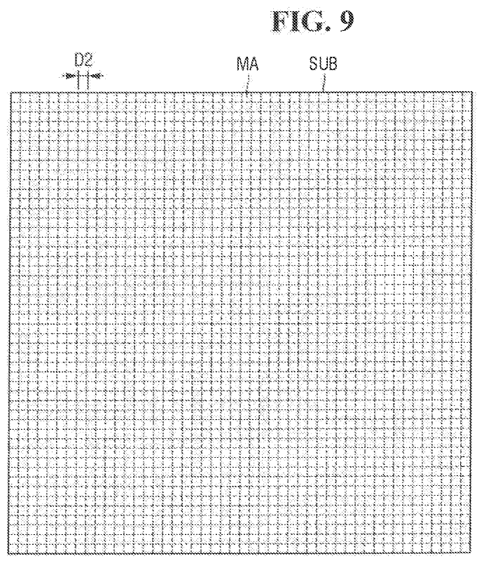

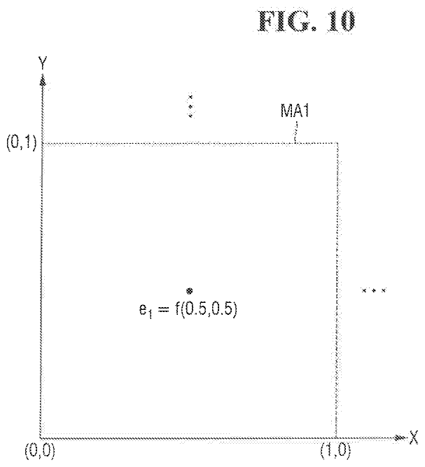

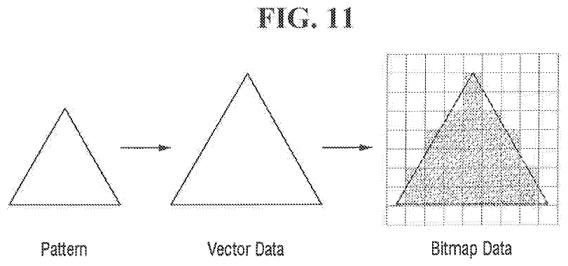

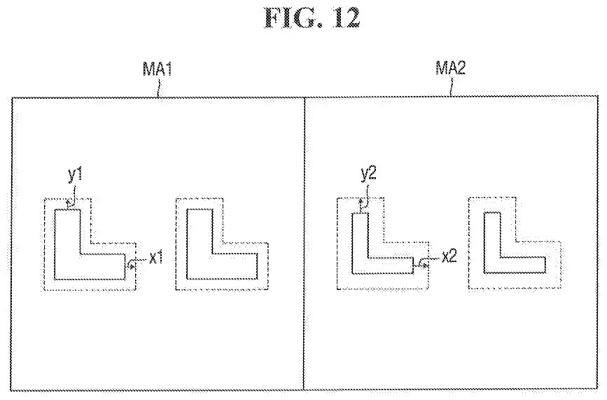

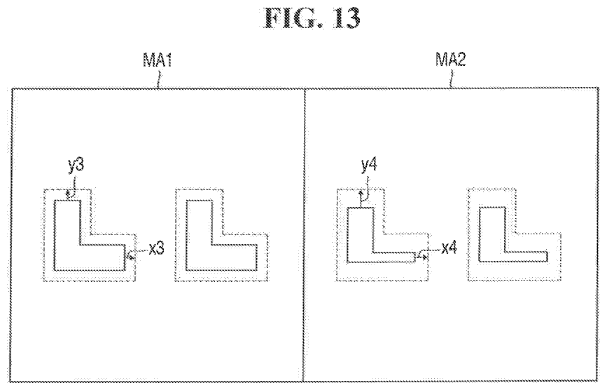

FIG. 5 is a flowchart illustrating a pattern width correction method according to an exemplary embodiment of the inventive concept. FIG. 6 is a diagram illustrating a first pattern formed on a substrate according to an exemplary embodiment of the inventive concept. FIG. 7 is a diagram illustrating a width of the first pattern of FIG. 6 according to an exemplary embodiment of the inventive concept. FIG. 8 is a diagram illustrating a first relational expression between X-Y coordinates and an error of the width of the first pattern of FIG. 7 according to an exemplary embodiment of the inventive concept. FIGS. 9 and 10 are diagrams illustrating second error data and a manipulation area of a second distance according to an exemplary embodiment of the inventive concept. FIG. 11 is a diagram illustrating vector data and bitmap data according to an exemplary embodiment of the inventive concept. FIG. 12 is a diagram illustrating isotropic error correction according to an exemplary embodiment of the inventive concept. FIG. 13 is a diagram illustrating anisotropic error correction according to an exemplary embodiment of the inventive concept.

Referring to FIGS. 5 and 6, the pattern forming unit 110 may form a first pattern P1 having a first distance D1 on the substrate SUB using first pattern data (S510). According to an exemplary embodiment of the inventive concept, the first pattern data may be on/off data for forming the first pattern P1. In other words, the pattern forming unit 110 may form the first pattern P1 on the substrate SUB by turning the OMD 111 on/off on the basis of the first pattern data. Additionally, the pattern forming unit 110 may control the stage 112 on the basis of the pattern data such that the first pattern P1 can be placed at the first distance D1. Referring to FIG. 6, the first pattern P1 may include 12 first patterns formed in the X direction of the substrate SUB and 14 first patterns formed in the Y direction of the substrate SUB. However, the inventive concept is not limited thereto. The number of first patterns P1 may be determined according to various criteria by those skilled in the art.

Referring to FIGS. 5 and 7, the pattern width measurement unit 120 may measure the width of the first pattern (S520). In other words, the pattern width measurement unit 120 may measure the width of each of the first patterns P1 arranged at the first distances D1 on the substrate SUB.

According to an exemplary embodiment of the inventive concept, when a pattern width is corrected, the pattern width may be isotropically corrected such that a degree of pattern correction in the X direction is isotropic with respect to a direction of pattern correction in the Y direction, or may be anisotropically corrected such that a degree of pattern correction in the X direction is anisotropic with respect to a degree of pattern correction in the Y direction. The former and latter may be referred to as isotropic error correction and anisotropic error correction, respectively.

The first pattern P1 may include X direction widths Wₓ₁ and Wₓ₂ and Y direction widths W_{y1} and W_{y2}. According to an exemplary embodiment of the inventive concept, when the pattern width correction method uses the isotropic error correction, a width of the first pattern may be defined according to Equation 1 below:

W̅=¼(Wₓ₁+Wₓ₂+w_{y1}+w_{y2}) [Equation 1]

On the other hand, according to an exemplary embodiment of the inventive concept, when the pattern width correction method uses the anisotropic error correction, an X component W̅ₓ and a Y component W̅_{y} of the width of the first pattern may be defined according to Equation 2 below:

W̅ₓ̅=½(Wₓ₁+Wₓ₂), W̅_̅{̅y̅}̅=½(W_{y1}W_{y2}) [Equation 2]

According to an exemplary embodiment of the inventive concept, the first error calculator 131 may generate first error data on the basis of X-Y coordinates on the substrate SUB and the measured width of the first pattern P1 (S530). As described above, the first error data may include the X-Y coordinates of the first pattern P1 on the substrate and a width error of the first pattern P1.

According to an exemplary embodiment of the inventive concept, when the pattern width correction method uses the isotropic error correction, a width error eᵢ of the first pattern P1 may be defined according to Equation 3 below:

eᵢ=W̅−tᵢ=¼(Wₓ₁+Wₓ₂+W_{y1}+W_{y2})−tᵢ [Equation 3]

where tᵢ is a target width of the first pattern P1.

According to an exemplary embodiment of the inventive concept, when the pattern width correction method uses the anisotropic error correction, width error eₓ and e_{y} of the first pattern P1 may be defined according to Equation 4 below:

eₓ=W̅ₓ̅−tₓ=½(Wₓ₁+Wₓ₂)−tₓ,

e_{y}=W̅_̅{̅y̅}̅−t_{y}=½(W_{y1}+W_{y2})−t_{y} [Equation 4]

where tₓ is a target width of the first pattern P1 in the X direction, and t_{y} is a target width of the first pattern P1 in the Y direction.

Referring to FIGS. 5 and 8, the regression analyzer 132 may perform regression analysis on the first error data to generate a first relational expression 810 (e=f(x,y)) for X-Y coordinates on the substrate SUB and an error e of the pattern width (S540). Dots shown in FIG. 8 refer to the first error data generated by the first error calculator 131, and a surface shown in FIG. 8 refers to the first relational expression 810 derived by performing regression analysis on the dots, e.g., the first error data. In other words, the generating of the first error data including the width error of the first patterns P1 arranged at the first distances D1 may be a sampling process for deriving the first relational expression 810.

In exemplary embodiments of the inventive concept, the first relational expression 810 may be a third-order polynomial. According to an exemplary embodiment of the inventive concept, when the pattern width correction method uses the isotropic error correction, the first relational expression 810 may be represented according to Equation 5 below:

eᵢ=a₁+a₂x+a₃y+a₄x²+a₅xy+a₆y²+a₇x³+a₈x²y+a₉x²+a₉xy²+a₁₀y³ [Equation 5]

In exemplary embodiments of the inventive concept, when it is assumed that the number of pieces of the first error data generated by the first error calculator 131 is N (here, N>10), Equation 5 may be expressed as the matrix of Equation 6 below:

$${[ Equation 6 ] \\ [ \begin{matrix}{e}_{i 1} \\ {e}_{i 2} \\ ⋮ \\ {e}_{iN}\end{matrix} ]}_{N \times 1} = {{[ \begin{matrix}1 & {x}_{1} & {y}_{1} & ⋯ & {y}_{1}^{3} \\ 1 & {x}_{2} & {y}_{2} & ⋯ & {y}_{2}^{3} \\ ⋮ & ⋮ & ⋮ & ⋱ & ⋮ \\ 1 & {x}_{N} & {y}_{N} & ⋯ & {y}_{N}^{3}\end{matrix} ]}_{N \times 10} [ \begin{matrix}{a}_{1} \\ {a}_{2} \\ ⋮ \\ {a}_{10}\end{matrix} ]}_{10 \times 1} \to {e}_{i} = M \cdot {a}_{k}$$

Here, the coefficient aₖ of Equation 6 may be approximated using an inverse matrix of the matrix M as shown in Equation 7 below. The inverse matrix M+ of the matrix M may be found using a pseudo inverse matrix as shown in Equation 8 below or using singular value decomposition (SVD) as shown in Equation 9 below.

α̅ₖ̅=M⁺·e_{i.} [Equation 7]

M⁺=(M^{T}M)⁻¹M^{T} [Equation 8]

M⁺=VΣ⁺U^{T}. [Equation 9]

According to an exemplary embodiment of the inventive concept, when the pattern width correction method uses the anisotropic error correction, the first relational expression 810 may be represented according to Equation 10 below:

eₓ=b₁+b₂x+b₃y+c₄x²+b₅xy+b₆y²+b₇x³+b₈x²y+b₉xy²+b₁₀y³,

e_{y}=c₁+c₂x+c₃y+c₄x²+c₅xy+c₆y²+c₇x³+c₈x²y+c₉xy²+c₁₀y³. [Equation 10]

Here, the coefficients bₖ and cₖ of Equation 10 may be found through approximation using the methods shown in FIGS. 7 to 9.

Equations 5 to 10 assume that the first relational expression 810 is a third-order polynomial. However, this is merely an exemplary illustration, and the inventive concept is not limited thereto. For example, the first relational expression 810 may not be a polynomial, and the regression analyzer 132 may perform regression analysis on the first error data using a neural network to generate the first relational expression 810.

Referring to FIGS. 5, 9, and 10, the second error calculator 133 may generate the second error data by substituting coordinates of a center point of each manipulation area MA into the first relational expression 810 (S550). The manipulation area MA refers to a minimum unit to be corrected.

In exemplary embodiments of the inventive concept, the substrate SUB may be divided into manipulation areas MAs having a second distance D2. Here, the second distance D2 may be smaller than the first distance D1. According to an exemplary embodiment of the inventive concept, the correction of the pattern width may be performed in units of the manipulation area (MA). Second error data eₘ for each manipulation MA may be represented according to Equation 11 below:

eₘ=f(center point coordinate of m^{th} MA). [Equation 11]

For example, when it is assumed that the coordinates of the center point of a first manipulation area MA1 is (0.5, 0.5), the second error data of the first manipulation area MA1 may be e₁=f(0.5, 0.5).

Referring to FIGS. 5 and 11, the pattern data correction unit 134 may generate first vector data using the second error data (S560). For example, when the second error data of the first manipulation area MA1 is a negative number, the width of the pattern included in the first manipulation area MA1 may be formed to be smaller than the target width of the pattern. In this case, the pattern data correction unit 134 may generate the first vector data such that the width of the pattern included in the first manipulation area MA1 is inflated. For example, the first vector data may include X-Y coordinates of each of the vertices of the pattern. As another example, when the second error data of the first manipulation area MA1 is a positive number, the width of the pattern included in the first manipulation area MA1 may be formed to be wider than the target width of the pattern. In this case, the pattern data correction unit 134 may generate the first vector data such that the width of the pattern included in the first manipulation area MA1 is deflated.

In exemplary embodiments of the inventive concept, the pattern data correction unit 134 may convert the generated first vector data into first bitmap data (S570). The pattern data correction unit 134 may generate the second pattern data using the first bitmap data (S580). The second pattern data may refer to the corrected first pattern data.

In exemplary embodiments of the inventive concept, the pattern data correction unit 134 forms a second pattern using the corrected first pattern data, e.g., the second data pattern, and measures the width of the second pattern. The correction process ends when the width of the second pattern is smaller than a desired allowable range. Operations S510 to S580 for the correction are performed when the width of the second pattern is greater than or equal to the desired allowable range (S590).

Referring to FIG. 12, when the isotropic error correction is performed, a degree of pattern width correction in an X direction (x1) of the first manipulation area MA1 may be substantially the same as a degree of pattern width correction degree in a Y direction (y1). Here, the expression “substantially the same” includes a process error. Likewise, a degree of pattern width correction in an X direction (x2) of a second manipulation area MA2 may be substantially the same as a degree of pattern width correction in a Y direction (y2) of the second manipulation area MA2. In exemplary embodiments of the inventive concept, since the correction of the pattern width is performed for each manipulation area MA, patterns included in the same manipulation area MA may be corrected by the same degree of correction.

Referring to FIG. 13, when the anisotropic error correction is performed, a degree of pattern width correction in an X direction (x3) of the first manipulation area MA1 may be substantially the same as a degree of pattern width correction in a Y direction (y3). Here, the expression “substantially the same” includes a process error. Meanwhile, a degree of pattern width correction in an X direction (x4) of the second manipulation area MA2 may be substantially the same as a degree of pattern width correction in a Y direction (y4) of the second manipulation area MA2. In exemplary embodiments of the inventive concept, since the anisotropic error correction calculates a degree of correction in an X direction and a degree of correction in a Y direction separately, a degree of pattern width correction in the X direction and a degree of pattern width correction in the Y direction may be different from each other.

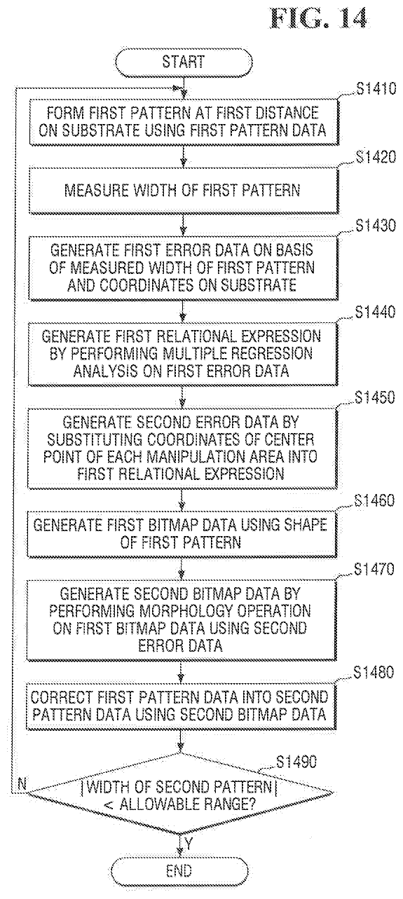

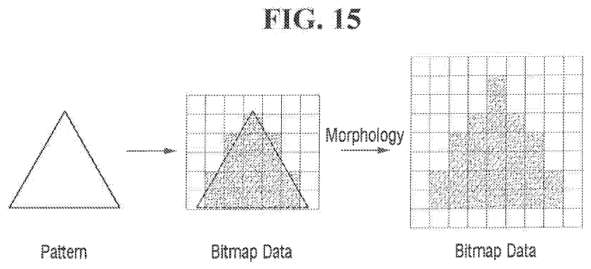

FIG. 14 is a flowchart illustrating a pattern width correction method according to an exemplary embodiment of the inventive concept. FIG. 15 is a diagram illustrating second bitmap data generated by performing a morphology operation on first bitmap data according to an exemplary embodiment of the inventive concept.

Since operations S1410 to 1450 of FIG. 14 are substantially the same as operations S510 to S550 of FIG. 5, and operation S1490 of FIG. 14 is substantially the same as operation S590 of FIG. 5, descriptions of operations S1410 to S1450 and S1490 will be omitted.

Referring to FIGS. 14 and 15, the pattern data correction unit 134 may generate the first bitmap data using the shape of the first pattern P1 (S1460). The pattern data correction unit 134 may generate second bitmap data by performing the morphology operation on the first bitmap data on the basis of second error data (S1470). For example, when the second error data of the first manipulation area MA1 is a negative number, the pattern data correction unit 134 may perform a dilation morphology operation on the first bitmap data to generate the second bitmap data. As another example, when the second error data of the first manipulation area MA1 is a positive number, the pattern data correction unit 134 may perform an erosion morphology operation on the first bitmap data to generate the second bitmap data. In exemplary embodiments of the inventive concept, the pattern data correction unit 134 may generate second pattern data using the first bitmap data (S1480). The second pattern data may be obtained by correcting the first pattern data.

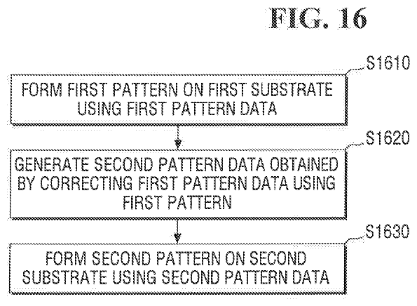

FIG. 16 is a flowchart illustrating a method of manufacturing a semiconductor apparatus using a pattern width correction method according to an exemplary embodiment of the inventive concept.

Referring to FIG. 16, a first pattern is formed on a first substrate using first pattern data (S1610). Second pattern data is generated by correcting the first pattern data using the formed first pattern (1620). Here, the generation of the second pattern data by correcting the first pattern data may be substantially the same as operations S520 to S590 of FIG. 5 or operations S1420 to S1490 of FIG. 14. A second pattern is formed on a second substrate using the corrected first pattern data, e.g., the second pattern data (S1630). The semiconductor apparatus may be manufactured by performing the remaining processes on the second substrate. In other words, the semiconductor apparatus according to an exemplary embodiment of the inventive concept may be a semiconductor apparatus including the second pattern.

While the inventive concept has been particularly shown and described with reference to exemplary embodiments thereof, it will be understood by those of ordinary skill in the art that various changes in form and details may be made thereto without departing from the spirit and scope of the inventive concept as set forth by the following claims.

What is claimed is:

1. A pattern width correction system comprising:
a pattern width measurement unit configured to measure a width of a first pattern formed at a first distance, wherein the first pattern is formed by irradiating first light modulated using first pattern data;
a first error data calculator configured to generate first error data on the basis of the measured width of the first pattern;
a regression analyzer configured to perform regression analysis on the first error data to generate a first relational expression between X-Y coordinates of the first pattern and a width error of the first pattern;
a second error data calculator configured to generate second error data in a manipulation area having a second distance by using the first relational expression; and
a pattern data correction unit configured to generate second pattern data by correcting the first pattern data on the basis of the second error data.

2. The pattern width correction system of claim 1, wherein the pattern data correction unit generates first vector data on the basis of the second error data, converts the first vector data to generate first bitmap data, and corrects the first pattern data on the basis of the first bitmap data to generate the second pattern data.

3. The pattern width correction system of claim 1, wherein the pattern data correction unit generates first bitmap data using a shape of the first pattern, modifies the first bitmap data on the basis of the second error data to generate second bitmap data, and corrects the first pattern data on the basis of the second bitmap data to generate the second pattern data.

4. The pattern width correction system of claim 1,
wherein the pattern width measurement unit measures a width of a second pattern formed using the second pattern data,
wherein the first error data calculator generates third error data on the basis of the measured width of the second pattern, and
wherein the pattern data correction unit determines whether a size of the third error data is smaller than a desired allowable range.

5. The pattern width correction system of claim 4, wherein when the size of the third error data is greater than or equal to the desired allowable range,
the regression analyzer performs regression analysis on the third error data to calculate a second relational expression between X-Y coordinates of the second pattern and a width error of the second pattern,
the second error data calculator generates fourth error data in the manipulation area using the second relational expression, and
the pattern data correction unit corrects the second pattern data on the basis of the fourth error data to generate third pattern data.

6. The pattern width correction system of claim 1, wherein the first error data corresponds to a difference between the measured width of the first pattern and a desired target width of the first pattern.

7. The pattern width correction system of claim 6,
wherein the first error data includes X-component error data and Y-component error data,
wherein the X-component error data corresponds to a difference between an average of an X component of the measured width of the first pattern and an X component of the desired target width of the first pattern, and
wherein the Y-component error data corresponds to a difference between an average of a Y component of the measured width of the first pattern and a Y component of the desired target width of the first pattern.

8. The pattern width correction system of claim 6, wherein the first error data corresponds to a difference between an entire average of the measured width of the first pattern and the desired target width of the first pattern.

9. The pattern width correction system of claim 1, wherein the regression analyzer generates the first relational expression using a pseudo inverse matrix.

10. The pattern width correction system of claim 1, wherein the first distance is greater than the second distance.

11. The pattern width correction system of claim 1, wherein the second error data is generated by substituting coordinates of a center point of the manipulation area into the first relational expression.

12. A pattern width correction system comprising:
a pattern forming unit configured to form a first pattern on a substrate using first pattern data;
a pattern width measurement unit configured to measure a width of the first pattern; and
a pattern width correction unit configured to generate first error data of the measured width of the first pattern, generate a first relational expression of a location of the substrate and a width error of the first pattern using the first error data, calculate a first width error of the first pattern at a first location of the substrate by substituting the first location into the first relational expression, and generate second pattern data obtained by correcting the first pattern data at the first location using the first width error of the first pattern at the first location.

13. The pattern width correction system of claim 12, wherein the pattern width correction unit generates the first relational expression using regression analysis.

14. The pattern width correction system of claim 12, wherein the pattern width correction unit generates first vector data on the basis of the first width error of the first pattern at the first location, generates first bitmap data using the first vector data, and generates the second pattern data using the first bitmap data.

15. The pattern width correction system of claim 12, wherein the pattern width correction unit generates first bitmap data on the basis of a shape of the first pattern, performs a morphology operation on the first bitmap data on the basis of the first width error of the first pattern at the first location to generate second bitmap data, and generates the second pattern data using the second bitmap data.

16. The pattern width correction system of claim 12, wherein the first error data corresponds to a difference between the measured width of the first pattern and a desired target width of the first pattern.

17. A method of manufacturing a semiconductor apparatus, the method comprising:
forming a first pattern on a first substrate using first pattern data;
generating second pattern data obtained by correcting the first pattern data using the first pattern; and
forming a second pattern on a second substrate using the second pattern data,
wherein the generating of the second pattern data comprises measuring a width of the first pattern, generating first error data of the measured width of the first pattern, generating a first relational expression between a location of the first substrate and a width error of the first pattern using the first error data, calculating a first width error of the first pattern at a first location of the first substrate by substituting the first location into the first relational expression, and generating the second pattern data using the first width error of the first pattern at the first location.

18. The method of claim 17, wherein the first relational expression is generated by performing regression analysis on the first error data.

19. The method of claim 17, wherein the generating of the second pattern data using the first width error of the first pattern at the first location comprises generating first vector data on the basis of the first width error of the first pattern at the first location, generating first bitmap data using the first vector data, and generating the second pattern data using the first bitmap data.

20. The method of claim 17, wherein the generating of the second pattern data using the first width error of the first pattern at the first location comprises generating first bitmap data on the basis of a shape of the first pattern, performing a morphology operation on the first bitmap data on the basis of the first width error of the first pattern at the first location to generate second bitmap data, and generating the second pattern data using the second bitmap data.
